(19) United States
(12) Patent Application Publication
(10) Pub. No.: US 2025/0142975 A1
(43) Pub. Date: May 1, 2025

(54) SEMICONDUCTOR DEVICE

(71) Applicant: Renesas Electronics Corporation, Tokyo (JP)

(72) Inventors: Yasuyuki MORISHITA, Tokyo (JP); Koki NARITA, Tokyo (JP); Satoshi MAEDA, Tokyo (JP)

(21) Appl. No.: 18/915,623

(22) Filed: Oct. 15, 2024

(30) Foreign Application Priority Data
Nov. 1, 2023 (JP) 2023-187662

(51) Int. Cl. H01L 27/02; H02H 9/04

(52) U.S. Cl. CPC H10D 89/819; H02H 9/044

(57) ABSTRACT

A semiconductor device includes a semiconductor chip having a plurality of layers formed on a surface. Here, a power supply wiring to which a power supply voltage is supplied, a ground wiring to which a ground voltage is supplied, MOS transistors connected to the power supply and ground wirings, and a trigger circuit, which is electrically connected to a gate electrode of the MOS transistor via a first wiring, are formed in the plurality of layers. The MOS transistors and the trigger circuit are formed in a first layer, the first wiring is formed in a second layer which is an upper layer of the first layer, and the first wiring includes a first portion extending in a first direction and a second portion which extends in a second direction intersecting the first direction and is electrically connected to the first portion.

### CROSS-REFERENCE TO RELATED APPLICATIONS

The disclosure of Japanese Patent Application No. 2023-187662 filed on Nov. 1, 2023 including the specification, drawings and abstract is incorporated herein by reference in its entirety.

### BACKGROUND

The present invention relates to a semiconductor device, for example, a semiconductor device including an electro static discharge (ESD) protection circuit.

There are disclosed techniques listed below.
[Patent Document 1] U.S. Pat. No. 7,397,642

For example, Patent Document 1 discloses an ESD protection circuit. Patent Document 1 discloses an ESD protection circuit including a field effect transistor (hereinafter, also referred to as a MOS transistor) having a low withstand voltage. That is, Patent Document 1 discloses an ESD protection circuit having a configuration in which source-drain paths of two N-channel MOSFETs (hereinafter, also referred to as NMOS transistors) each having a withstand voltage (3.3 V) lower than a power supply voltage (5 V), supplied to a main discharge wiring to which the ESD protection circuit is connected, are connected in series to the main discharge wiring.

### SUMMARY

As will be described later with reference to the drawings, as a result of studies conducted by the present inventors prior to the present invention, and the present inventors have found a problem that, in a semiconductor device including an ESD protection circuit, sufficient wiring resources are not allocated to a wiring in the ESD protection circuit because a large number of wiring resources are allocated to a main discharge wiring connected to the ESD protection circuit, whereby an ESD protection function is deteriorated.

Patent Document 1 does not pay attention to the main discharge wiring and the wiring in the ESD protection circuit, and the above-described problem is not indicated in Patent Document 1.

An outline of a representative of embodiments disclosed in the present application will be briefly described as follows.

That is, a semiconductor device according to one embodiment includes a semiconductor chip having a plurality of layers formed on a surface. Here, in the plurality of layers, a first power supply wiring to which a power supply voltage is supplied, a second power supply wiring to which a ground voltage is supplied, a MOS transistor connected to the first power supply wiring and the second power supply wiring and configured to electrically short-circuit the first power supply wiring and the second power supply wiring, and a trigger circuit electrically connected to a first gate electrode of the MOS transistor via a first wiring and configured to output a first control signal for controlling the first gate electrode, are formed, the MOS transistor and the trigger circuit are formed in a first layer of the plurality of layers, the first wiring is formed in a second layer which is an upper layer of the first layer, and the first wiring includes a first portion extending in a first direction and a second portion which extends in a second direction intersecting the first direction and is electrically connected to the first portion.

Other problems and novel features will be apparent from description of the present specification and the attached drawings.

According to one embodiment, it is possible to provide the semiconductor device capable of suppressing the deterioration of the ESD protection function.

### BRIEF DESCRIPTION OF THE DRAWINGS

FIG. 1 is a block diagram illustrating a configuration of a semiconductor device according to a first embodiment.

FIG. 2 is a block diagram illustrating a configuration of an ESD protection circuit according to the first embodiment.

FIG. 3 is a plan view illustrating a schematic layout of the ESD protection circuit according to the first embodiment.

FIG. 4A is a diagram for describing a layer according to the first embodiment.

FIG. 4B is a diagram for describing a layer according to the first embodiment.

FIG. 4C is a diagram for describing a layer according to the first embodiment.

FIG. 4D is a diagram for describing a layer according to the first embodiment.

FIG. 4E is a diagram for describing a layer according to the first embodiment.

FIG. 5 is a plan view illustrating a wiring layout in a dedicated wiring region according to the first embodiment.

FIG. 6A is a diagram for describing a layer according to the first embodiment.

FIG. 6B is a diagram for describing a layer according to the first embodiment.

FIG. 6C is a diagram for describing a layer according to the first embodiment.

FIG. 6D is a diagram for describing a layer according to the first embodiment.

FIG. 6E is a diagram for describing a layer according to the first embodiment.

FIG. 7 is a plan view illustrating a wiring layout in a dedicated wiring region according to the first embodiment.

FIG. 8 is a plan view illustrating a layout of a power supply wiring and a ground wiring according to the first embodiment.

FIGS. 9A to 9C are diagrams for describing a discharge switch circuit according to the first embodiment.

FIG. 10 is a block diagram illustrating a configuration of an ESD protection circuit according to a second embodiment.

FIG. 11 is a plan view illustrating a layout of the ESD protection circuit according to the second embodiment.

FIGS. 12A and 12B are diagrams for describing an ESD protection circuit studied by the present inventors prior to the present invention.

FIG. 13 is a plan view illustrating a schematic layout of the ESD protection circuit illustrated in FIG. 12A.

### DETAILED DESCRIPTION

Hereinafter, each embodiment of the invention will be described with reference to the drawings. Incidentally, the disclosure is mere an example, and it is a matter of course that any alteration that is, easily conceivable, if necessary, while keeping a gist of the invention by a person skilled in the art, is included in the invention.

In addition, the same reference signs are applied to the same elements that have been described in relation to the foregoing drawings in the present specification and the respective drawings, and detailed descriptions thereof will be appropriately omitted in some cases.

### Studies by Present Inventors

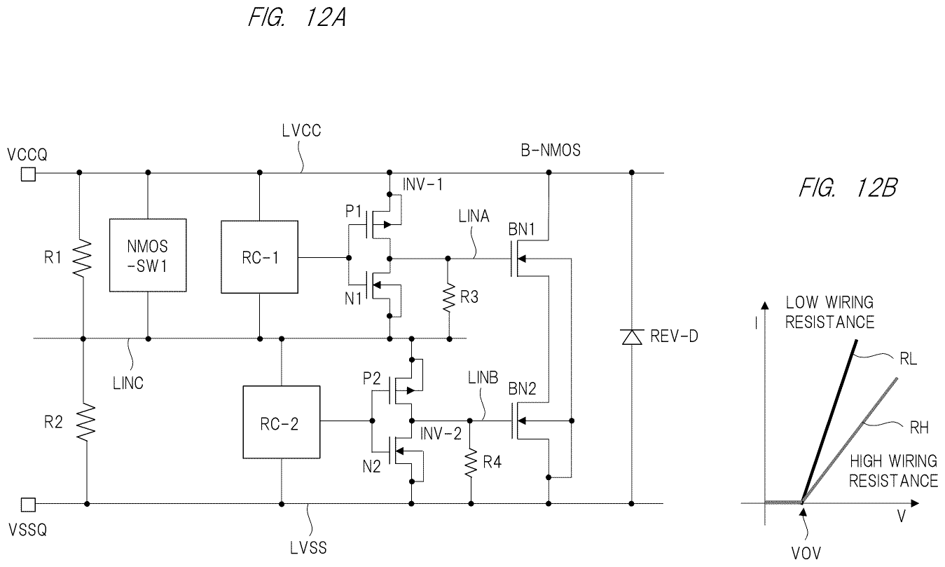

First, matters studied by the present inventors will be described with reference to the drawings. FIGS. 12A and 12B is diagrams for describing an ESD protection circuit studied by the present inventors prior to the present invention. Here, FIG. 12A is a block diagram illustrating a configuration of an ESD protection circuit ESDP, and FIG. 12B is a characteristic diagram illustrating characteristics of the ESD protection circuit ESDP.

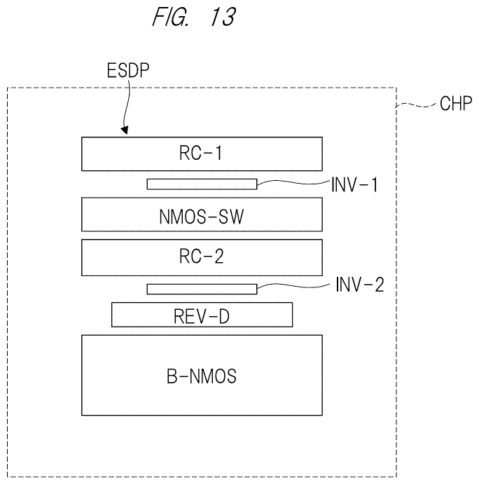

In addition, FIG. 13 is a plan view illustrating a schematic layout of the ESD protection circuit illustrated in FIGS. 12A and 12B. The ESD protection circuit ESDP is formed on a semiconductor chip CHP constituting a semiconductor device. Although a plurality of circuit blocks including the ESD protection circuit ESDP are formed on the semiconductor chip CHP, FIG. 13 illustrates only the schematic layout of the ESD protection circuit ESDP formed on a part of the semiconductor chip CHP in order to avoid complication of the drawing.

In FIG. 12A, VCCQ indicates a power supply terminal to which a power supply voltage VCC is supplied, and VSSQ indicates a ground terminal to which a ground voltage VSS is supplied. A power supply wiring (hereinafter, also referred to as a first power supply wiring) LVCC is connected to the power supply terminal VCCQ, and a ground wiring (hereinafter, also referred to as a second power supply wiring) LVSS is connected to the ground terminal VSSQ. The ESD protection circuit ESDP is connected between the power supply wiring LVCC and the ground wiring LVSS. For example, when a steep high voltage is applied to the power supply terminal VCCQ, current flows (discharging is performed) through the power supply wiring LVCC, the ESD protection circuit ESDP, and the ground wiring LVSS. As a result, it is possible to prevent circuit blocks (not illustrated), such as a processing circuit, which are connected between the power supply wiring LVCC and the ground wiring LVSS and operates using the power supply voltage VCC as an operating voltage, from being destroyed by the steep high voltage.

The power supply wiring LVCC and the ground wiring LVSS serve as paths at the time of discharging, and thus can be considered as a main discharge wiring (main discharge path). The main discharge wiring is used not only as a path at the time of discharging but also as a role of supplying the operating voltage to a large number of circuit blocks, and thus configured using sufficient wiring resources so as to decrease wiring resistance.

The ESD protection circuit ESDP includes resistors R1 to R4, an NMOS switch circuit NMOS-SW1, time constant circuits (RC circuits) RC-1 and RC-2, inverter circuits INV-1 and INV-2, a discharge switch circuit B-NMOS, and a reverse diode REV-D.

In FIG. 12A, LINA to LINC indicate wirings (internal wirings) in the ESD protection circuit connecting circuits (including elements) constituting the ESD protection circuit ESDP. The resistor R1, the NMOS switch circuit NMOS-SW1, the time constant circuit RC-1, and the inverter circuit INV-1 are connected in parallel between the power supply wiring LVCC and the internal wiring LINC. In addition, the resistor R2, the time constant circuit RC-2, and the inverter circuit INV-2 are connected in parallel between the internal wiring LINC and the ground wiring LVSS. In addition, the discharge switch circuit B-NMOS is connected between the power supply wiring LVCC and the ground wiring LVSS. The discharge switch circuit B-NMOS includes two NMOS transistors BN1 and BN2. Source-drain paths of the two NMOS transistors BN1 and BN2 are connected in series between the power supply wiring LVCC and the ground wiring LVSS. Furthermore, output of the inverter circuit INV-1 is supplied to a gate electrode of the NMOS transistor BN1 via the internal wiring LINA, and output of the inverter circuit INV-2 is supplied to a gate electrode of the NMOS transistor BN2 via the internal wiring LINB.

For example, when a steep high voltage is applied to the power supply terminal VCCQ (when an ESD event occurs), this voltage increases voltages of the internal wirings LINC, LINA, and LINB, and both the NMOS transistors BN1 and BN2 are turned on. As a result, current flows through the discharge switch circuit B-NMOS in the ESD protection circuit ESDP, and the circuit blocks (not illustrated) connected to the power supply wiring LVCC are protected from the high voltage.

When viewed in a plan view, the circuits (NMOS-SW1, RC-1, RC-2, INV-1, INV-2, B-NMOS, and REV-D) constituting the ESD protection circuit ESDP are densely disposed on the semiconductor chip as illustrated in FIG. 13. Since wiring resources constituting the internal wirings LINA to LINC of the ESD protection circuit ESDP are smaller than the wiring resources constituting the main discharge wiring, wiring resistance of the internal wirings LINA to LINC is high. If the wiring resistance of the internal wirings LINA to LINC is high, when a steep high voltage is applied, voltages of the gate electrodes of the NMOS transistors BN1 and BN2 cannot be sufficiently increased, so that a protection function by the ESD protection circuit ESDP is deteriorated.

In FIG. 12B, “V” on the horizontal axis represents a voltage applied to the ESD protection circuit ESDP, that is, a voltage applied to the power supply terminal VCCQ with the ground terminal VSSQ as a reference, and “I” on the vertical axis represents current flowing through the ESD protection circuit ESDP. The main current flowing through the ESD protection circuit ESDP is current flowing between a source and a drain of each of the NMOS transistors BN1 and BN2 constituting the discharge switch circuit B-NMOS. When a high voltage VOV is applied to the power supply terminal VCCQ, the current I starts to flow as illustrated in FIG. 12B. In a case where the wiring resistance of the internal wirings LINA to LINC is high (reference sign RH), the flowing current I decreases as compared with a case where the wiring resistance is low (reference sign RL). Since the flowing current I decreases, the protection function by the ESD protection circuit ESDP is deteriorated.

According to embodiments described hereinafter, it is possible to suppress the deterioration of the ESD protection function.

### First Embodiment

### Configuration of Semiconductor Device

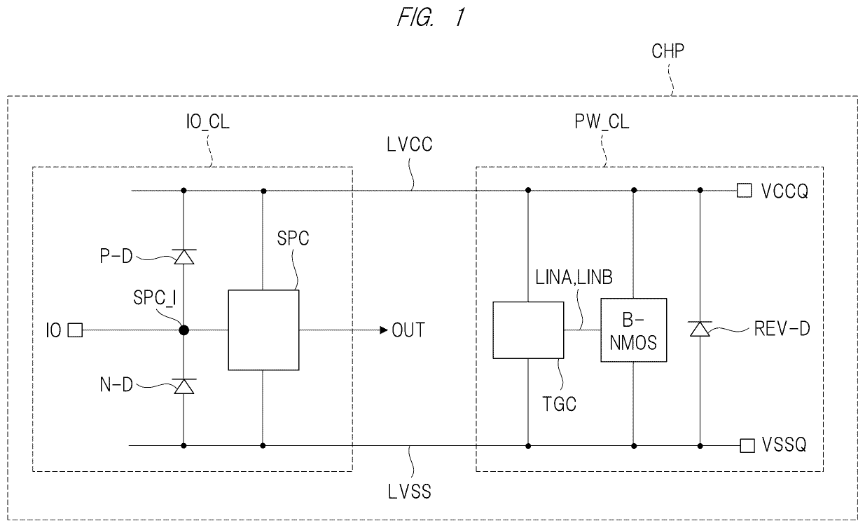

FIG. 1 is a block diagram illustrating a configuration of a semiconductor device according to a first embodiment. In FIG. 1, a portion CHP illustrated in a broken line indicates a semiconductor chip constituting the semiconductor device. Although not particularly limited, various circuit blocks are formed on the semiconductor chip CHP by a well-known semiconductor manufacturing technique. The semiconductor device is configured by sealing the semiconductor chip CHP with, for example, a package. Terminals (a power supply terminal, a ground terminal, an input/output terminal, and the like) of the circuit blocks formed in the semiconductor chip CHP are connected to an exposed terminal (not illustrated) of the semiconductor device.

Although various circuit blocks are formed in the semiconductor chip CHP as described above, only circuit blocks required for description are illustrated in FIG. 1 in order to avoid complication of the drawing.

In FIG. 1, two circuit blocks (cells) are illustrated as representatives. That is, FIG. 1 illustrates a power supply cell PW_CL and a signal cell IO_CL which are connected to common power supply wiring LVCC and ground wiring LVSS. Here, the power supply cell PW_CL corresponds to an ESD protection circuit, and the signal cell IO_CL corresponds to a protected circuit protected by the ESD protection circuit PW_CL when an ESD event occurs. Of course, the protected circuit is not limited to the signal cell IO_CL, and may be any circuit block connected to the same power supply wiring LVCC and ground wiring LVSS as the power supply cell PW_CL. In addition, the number of protected circuits is not limited to one, and the power supply cell PW_CL common to a plurality of protected circuit may be provided. In FIG. 1, reference signs VCCQ and VSSQ are the same as those described in FIGS. 12A and 12B, and denote the power supply terminal and the ground terminal connected to the power supply wiring and the ground wiring.

The power supply cell PW_CL (ESD protection circuit ESDP) includes a trigger circuit TGC, a discharge switch circuit B-NMOS, and a reverse diode REV-D connected in parallel between the power supply wiring LVCC and the ground wiring LVSS. The discharge switch circuit B-NMOS is connected to the trigger circuit TGC via internal wirings LINA and LINB, and is controlled by the trigger circuit TGC. Although the discharge switch circuit B-NMO and the trigger circuit TGC will be described later with reference to the drawings, for example, when a steep high voltage is applied to the power supply terminal VCCQ, the trigger circuit TGC controls the discharge switch circuit B-NMOS to be turned on such that the power supply wiring LVCC and the ground wiring LVSS are short-circuited by the discharge switch circuit B-NMOS to perform discharging.

The reverse diode REV-D has an anode connected to the ground wiring LVSS and a cathode connected to the power supply wiring LVCC, and performs discharging from the ground wiring LVSS toward the power supply wiring LVCC, for example, when a steep high voltage is applied to the ground terminal VSSQ, thereby providing protection.

Although not particularly limited, the signal cell IO_CL includes an input/output terminal IO, protection diodes P-D and N-D, and a signal processing circuit SPC. The signal processing circuit SPC and the series-connected protection diodes P-D and N-D are connected in parallel between the power supply wiring LVCC and the ground wiring LVSS. The signal processing circuit SPC performs a predetermined operation using a power supply voltage VCC as an operating voltage. For example, when the input/output terminal IO is an input terminal, a signal supplied to the input/output terminal is input to the signal processing circuit SPC, and the signal processing circuit SPC performs a predetermined operation on the input signal and outputs a signal OUT. The output signal OUT is supplied to another circuit block (not illustrated) and processed by the other circuit block.

The protection diode P-D has an anode connected to an input node SPC_I of the signal processing circuit SPC, connected to the input/output terminal IO, and a cathode connected to the power supply wiring LVCC. In addition, the protection diode N-D has a cathode connected to the input node SPC_I and an anode connected to the ground wiring LVSS. The protection diodes P-D and N-D operate to discharge current between the input/output terminal IO and the power supply wiring LVCC or the ground wiring LVSS when a high voltage or a negative voltage is applied to the input/output terminal IO, and function to prevent the signal processing circuit SPC from being destroyed by the high voltage or the negative voltage.

### Configuration of ESD Protection Circuit (Trigger Circuit and Discharge Switch Circuit)

Next, configurations of the trigger circuit TGC and the discharge switch circuit B-NMOS illustrated in FIG. 1 will be described with reference to the drawings.

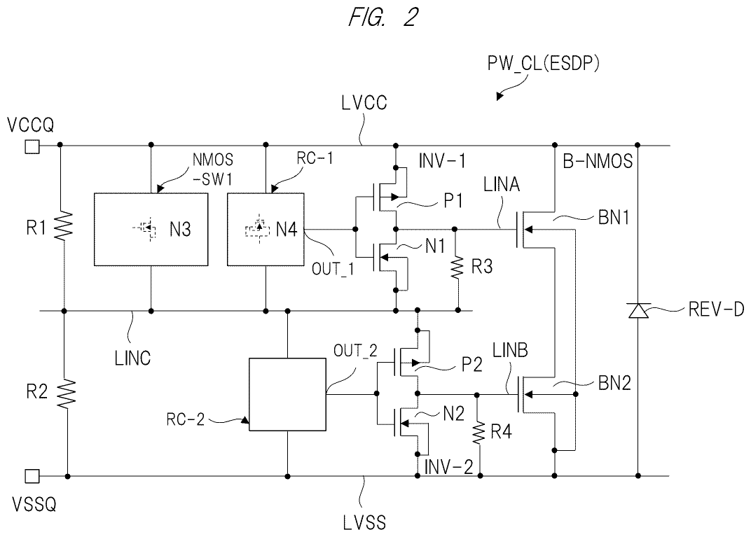

FIG. 2 is a block diagram illustrating a configuration of the ESD protection circuit according to the first embodiment. Here, the ESD protection circuit having a configuration similar to that illustrated in FIG. 12A is described as an example, but the invention is not limited thereto.

### Discharge Switch Circuit

In the ESD protection circuit ESDP (power supply cell PW_CL), the discharge switch circuit B-NMOS includes two NMOS transistors BN1 and BN2 whose source-drain paths are connected in series between the power supply wiring LVCC and the ground wiring LVSS. Incidentally, back gate electrodes of the NMOS transistors BN1 and BN2 are connected to the ground wiring LVSS. Here, an example in which the discharge switch circuit B-NMOS includes the two NMOS transistors connected in series is described, but the invention is not limited thereto. That is, the discharge switch circuit B-NMOS may include, for example, one MOS transistor, or may include three or more MOS transistors as described in a second embodiment.

### Trigger Circuit

In the ESD protection circuit ESDP, the trigger circuit TGC includes resistors R1 to R4, an NMOS switch circuit NMOS-SW1, time constant circuits RC-1 and RC-2, inverter circuits INV-1 and INV-2, and an internal wiring LINC. In addition, the trigger circuit TGC and gate electrodes of the NMOS transistors BN1 and BN2 constituting the discharge switch circuit B-NMOS are connected by the internal wirings LINA and LINB and the like, and the trigger circuit TGC supplies a first control signal for controlling the NMOS transistors BN1 and BN2 to the gate electrodes (corresponding to a first gate electrode) of the NMOS transistors BN1 and BN2.

In a case where it is considered that the discharge switch circuit B-NMOS is formed of two-stage NMOS transistors, the trigger circuit TGC can also be considered to be formed of two stages. That is, it can be considered that the time constant circuit RC-1 and the inverter circuit INV-1 constitute a stage corresponding to the NMOS transistor BN1, and the time constant circuit RC-2 and the inverter circuit INV-2 constitute a stage corresponding to the NMOS transistor BN2. In this case, it can be considered that the NMOS switch circuit NMOS-SW1 constitute the stage corresponding to the NMOS transistor BN1 or to be provided common to the two stages. In this case, the internal wirings LINA and LINB can be considered as wirings connecting the corresponding stages.

The resistors R1 and R2 are connected in series between the power supply wiring LVCC and the ground wiring LVSS. The internal wiring LINC is connected to a connection node connecting the resistors R1 and R2.

The NMOS switch circuit NMOS-SW1 and the time constant circuit RC-1 are connected in parallel between the power supply wiring LVCC and the internal wiring LINC.

In addition, the inverter circuit INV-1 is also connected between the power supply wiring LVCC and the internal wiring LINC, and the inverter circuit INV-1 operates using a voltage difference between the power supply wiring LVCC and the internal wiring LINC as an operating voltage. That is, source-drain paths of a P-channel MOS transistor (hereinafter, also referred to as a PMOS transistor) P1 and an NMOS transistor N1 constituting the inverter circuit INV-1 are connected in series between the power supply wiring LVCC and the internal wiring LINC.

An output signal OUT_1 of the time constant circuit RC-1 is supplied to gate electrodes of the PMOS transistor P1 and the NMOS transistor N1 constituting the inverter circuit INV-1. In addition, a connection node connecting a drain of the PMOS transistor P1 and a drain of the NMOS transistor N1 is connected to the internal wiring LINA, and the internal wiring LINA is connected to the gate electrode of the NMOS transistor BN1. Furthermore, a resistor R3 is connected between the internal wiring LINA and the internal wiring LINC.

The time constant circuit RC-2 is connected between the internal wiring LINC and the ground wiring LVSS. In addition, the inverter circuit INV-2 is connected between the internal wiring LINC and the ground wiring LVSS, and the inverter circuit INV-2 operates using a voltage difference between the internal wiring LINC and the ground wiring LVSS as an operating voltage. That is, source-drain paths of a PMOS transistor P2 and an NMOS transistor N2 constituting the inverter circuit INV-2 are connected in series between the internal wiring LINC and the ground wiring LVSS.

An output signal OUT_2 of the time constant circuit RC-2 is supplied to gate electrodes of the PMOS transistor P2 and the NMOS transistor N2 constituting the inverter circuit INV-2. In addition, a connection node connecting a drain of the PMOS transistor P2 and a drain of the NMOS transistor N2 is connected to the internal wiring LINB, and the internal wiring LINB is connected to the gate electrode of the NMOS transistor BN2. Furthermore, a resistor R4 is connected between the internal wiring LINB and the ground wiring LVSS.

Although not particularly limited, the NMOS switch circuit NMOS-SW1 includes an NMOS transistor N3 having a source-drain path connected between the power supply wiring LVCC and the internal wiring LINC. When a steep high voltage is applied to the power supply terminal VCCQ, the NMOS transistor N3 becomes conductive, and the NMOS switch circuit NMOS-SW1 raises a voltage of the internal wiring LINC toward a voltage at the power supply wiring LVCC.

The time constant circuit RC-1 includes a capacitive element. Although not particularly limited, the capacitive element includes an NMMOS transistor N4 having a source and a drain connected to each other. When a steep high voltage is applied to the power supply terminal VCCQ, charging (including discharging) of the capacitive element (NMOS transistor N4) is performed in the time constant circuit RC-1, and the time constant circuit RC-1 sets the output signal OUT_1 to a low level (voltage of the internal wiring LINC) and then sets the output signal OUT_1 to a high level (voltage of the power supply wiring LVCC) during a period in which the charging of the capacitive element is performed. That is, the time constant circuit RC-1 sets the output signal OUT_1 to the low level for a time determined by the capacitive element when a steep high voltage is applied to the power supply terminal VCCQ.

The time constant circuit RC-2 is configured similarly to the time constant circuit RC-1, and when a steep high voltage is applied to the power supply terminal VCCQ and the voltage of the internal wiring LINC rises, the time constant circuit RC-1 sets the output signal OUT_2 to the low level and then sets the output signal OUT_2 to the high level for a time determined by a capacitive element (not illustrated) included in the time constant circuit RC-2, similarly to the time constant circuit RC-2.

In response to the output signal OUT_1 of the time constant circuit RC-1, the inverter circuit INV-1 supplies the voltage (high level) of the power supply wiring LVCC or the voltage (low level) of the internal wiring LINC to the internal wiring LINA. This voltage propagates through the internal wiring LINA and is supplied to the gate electrode of the NMOS transistor BN1. Similarly, the inverter circuit INV-2 supplies the voltage (high level) of the internal wiring LINC or the voltage (low level) of the ground wiring to the internal wiring LINB in response to the output signal OUT_2 of the time constant circuit RC-2. This voltage propagates through the internal wiring LINB and is supplied to the gate electrode of the NMOS transistor BN2.

When a steep high voltage is applied to the power supply terminal VCCQ, each of the output signals OUT_1 and OUT_2 is set to the low level for the time determined by the capacitive element, and the inverter circuits INV-1 and INV-2 supply the high level to the internal wirings LINA and LINB, respectively. As a result, when a steep high voltage is applied to the power supply terminal VCCQ, both of the NMOS transistors BN1 and BN2 are in a conductive state, and the high voltage is discharged via the power supply wiring LVCC, the discharge switch circuit B-NMOS, and the ground wiring LVSS, and it is possible to prevent, for example, the signal cell IO_CL illustrated in FIG. 1 from being destroyed by the high voltage.

Note that, in a state where a steep high voltage is not applied to the power supply terminal VCCQ, that is, in a state where the power supply voltage VCC is supplied, the power supply voltage VCC is divided by the resistors R1 and R2, and a voltage (divided voltage) obtained by the division is applied to the internal wiring LINC. In this state, the NMOS transistor N3 in the NMOS switch circuit NMOS-SW1 is in a non-conductive state. In this state, the capacitive elements in the time constant circuits RC-1 and RC-2 are charged, and the output signals OUT_1 and OUT_2 are set to the high level. As a result, the NMOS transistors BN1 and BN2 constituting the discharge switch circuit B-NMOS are turned off, and the discharging by the ESD protection circuit ESDP is not performed. Incidentally, the resistors R3 and R4 are configured to reliability make the NMOS transistors BN1 and BN2 non-conductive in the state where the power supply voltage VCC is supplied to the power supply terminal VCCQ.

### Layout of ESD Protection Circuit

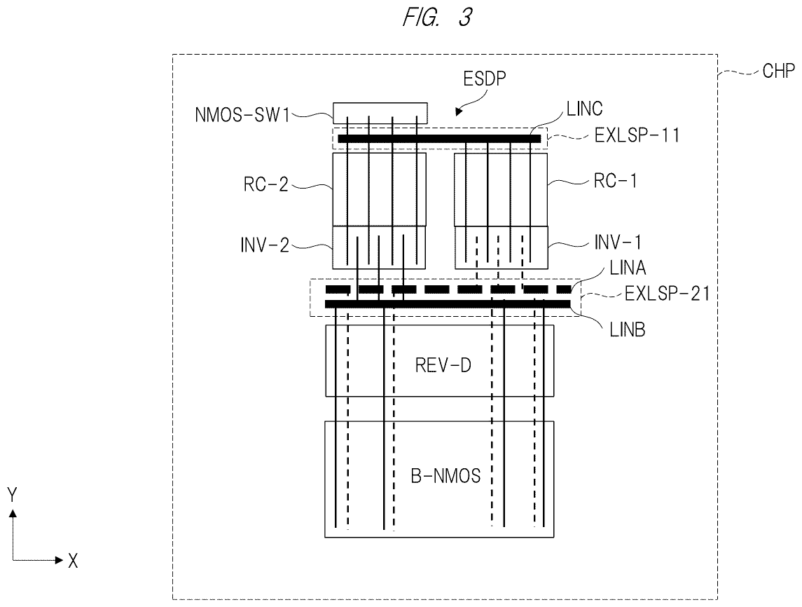

FIG. 3 is a plan view illustrating a schematic layout of the ESD protection circuit according to the first embodiment. As described with reference to FIG. 13, the ESD protection circuit ESDP is formed on the semiconductor chip CHP constituting the semiconductor device. FIG. 3 also illustrates only the schematic layout of the ESD protection circuit ESDP formed on a part of the semiconductor chip CHP in order to avoid complication of the drawing although a plurality of circuit blocks (for example, the signal cell IO_CL in FIG. 1 and the like) including the ESD protection circuit ESDP are formed on the semiconductor chip CHP illustrated in a broken line.

In the following description regarding the layout, the horizontal direction in the drawings is an X direction (first direction), and a direction intersecting the X direction, that is, the vertical direction in the drawings is a Y direction (second direction). In the drawings related to the layout including FIG. 3, the X direction and the Y direction are represented by arrows denoted by reference signs X and Y, respectively.

The layout of the ESD protection circuit ESDP according to the first embodiment is different from the layout of the ESD protection circuit illustrated in FIG. 13 in a plan view in which the main surface of the semiconductor chip CHP is viewed from That is, the layout of the ESD protection circuit above. according to the first embodiment is provided with dedicated wiring regions (dedicated wiring spaces) in which the internal wirings (for example, LINA to LINC of FIG. 2) of the ESD protection circuit ESDP are disposed. Wirings connecting the circuits constituting the ESD protection circuit are bundled by the internal wirings disposed in the dedicated wiring regions, so that it is possible to reduce wiring resistance of the wirings connecting the circuits, and to suppress the deterioration of the ESD protection function.

In FIG. 3, the dedicated wiring regions are denoted by reference signs EXLSP-11 and EXLSP-21. The layout of the ESD protection circuit ESDP will be described in detail as follows.

In FIG. 3, the discharge switch circuit B-NMOS, the reverse diode REV-D, the inverter circuits INV-2 and INV-1, the time constant circuits RC-2 and RC-1, and the NMOS switch circuit NMOS-SW1 are disposed in this order in the Y direction from the bottom to the top of the paper surface. In this case, the inverter circuit INV-2 and the inverter circuit INV-1 are disposed in this order in the X direction horizontally from the left of the paper surface of FIG. 3, and similarly, the time constant circuits RC-2 and RC-1 are disposed in this order horizontally from the left to the side of the paper surface.

As illustrated in FIG. 3, the dedicated wiring region EXLSP-11 is disposed above the time constant circuits RC-2 and RC-1, and is partially disposed between the time constant circuit RC-2 and the NMOS switch circuit NMOS-SW1. In addition, the dedicated wiring region EXLSP-21 is disposed between the inverter circuits INV-2 and INV-1 and the reverse diode REV-D as illustrated in FIG. 3.

Although will be described later, a plurality of wirings are disposed in the dedicated wiring region EXLSP-11, and the plurality of wirings are electrically connected to a wiring of the NMOS switch circuit NMOS-SW1, a wiring of the time constant circuit RC-2, a wiring of the time constant circuit RC-1, a wiring of the inverter circuit INV-2, and a wiring of the inverter circuit INV-1. It can be considered that the plurality of wirings disposed in the dedicated wiring region EXLSP-11 constitute the internal wiring LINC illustrated in FIG. 2.

Although will be described later, two wirings each including a plurality of wirings are disposed in the dedicated wiring region EXLSP-21. In FIG. 3, the two wirings are distinguished by a solid line and a broken line. One wiring (broken line) is electrically connected to the wiring of the inverter circuit INV-1 and the discharge switch circuit B-NMOS, and the other wiring (solid line) is electrically connected to the wiring of the inverter circuit INV-2 and the discharge switch circuit B-NMOS. It can be considered that broken-line wirings and solid-line wirings disposed in the dedicated wiring region EXLSP-21 form the internal wiring LINA illustrated in FIG. 2 and the internal wiring LINB illustrated in FIG. 2, respectively.

Incidentally, the resistors R1 to R4 illustrated in FIG. 2 are omitted in FIG. 3. Similarly, resistors corresponding to the resistors R1 to R4 are omitted in the following drawings related to the layout.

### Semiconductor Layer and Wiring Layer

Elements such as a MOS transistor and an internal wiring (including LINA to LINC and the wirings connecting circuits) constituting the ESD protection circuit ESDP, the power supply wiring LVCC, the ground wiring LVSS, and the like are formed of a plurality of layers (including a semiconductor layer such as a diffusion region and a wiring layer) formed on the surface of the semiconductor chip CHP.

For example, in the case of the MOS transistor, a diffusion region forming a source region, a drain region, and the like and a gate electrode provided with an interposing gate insulating film are formed on the surface of the semiconductor chip CHP, thereby forming the MOS transistor. In the present specification, description will be given assuming that the diffusion region forming the source region and the drain region and the gate electrode disposed with the interposing gate insulating film correspond to one layer (hereinafter, also referred to as a diffusion layer or a first layer) formed on the surface of the semiconductor chip CHP.

In the first embodiment, a plurality of wiring layers are formed on the diffusion layer with the surface of the semiconductor chip CHP as a reference. Each of the wiring layers is a conductive metal layer, and for example, fourteen wiring layers (metal wiring layers, hereinafter also referred to as metal layers) are formed above the diffusion layer. In this case, an insulating layer for electrical insulation between layers is formed between the diffusion layer and a metal layer (hereinafter, also referred to as a first metal layer) closest to the diffusion layer and between metal layers close to each other in an upper layer of the first metal layer. In order to form a desired circuit block, a contact hole is formed in the insulating layer between the diffusion layer and the first metal layer, and the diffusion layer and a first-layer wiring formed using the first metal layer are electrically connected via the contact hole. In addition, the insulating layer between the metal layers is also opened as necessary, and wirings formed using the metal layers are electrically connected by a via-hole.

Hereinafter, description will be given with reference to the drawings. Hereinafter, the ESD protection circuit ESDP illustrated in FIG. 3 will be described separately for a region including the dedicated wiring region EXLSP-21 and a region including the dedicated wiring region EXLSP-11.

Region including Dedicated Wiring Region EXLSP-21

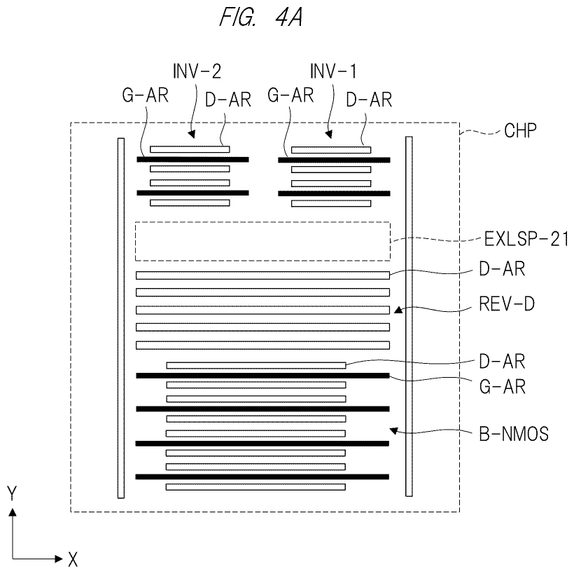

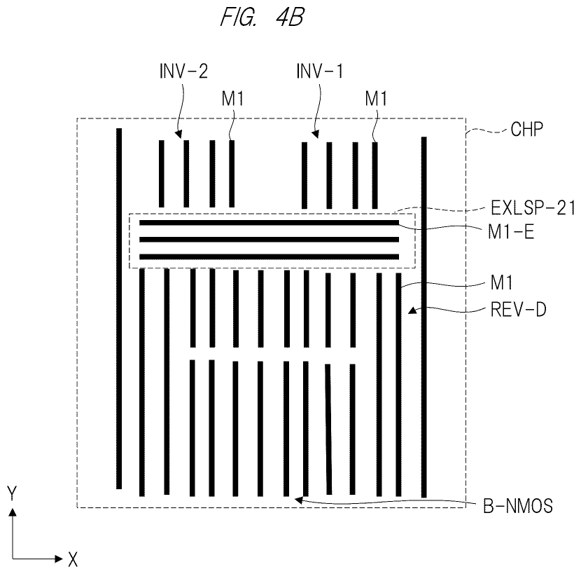

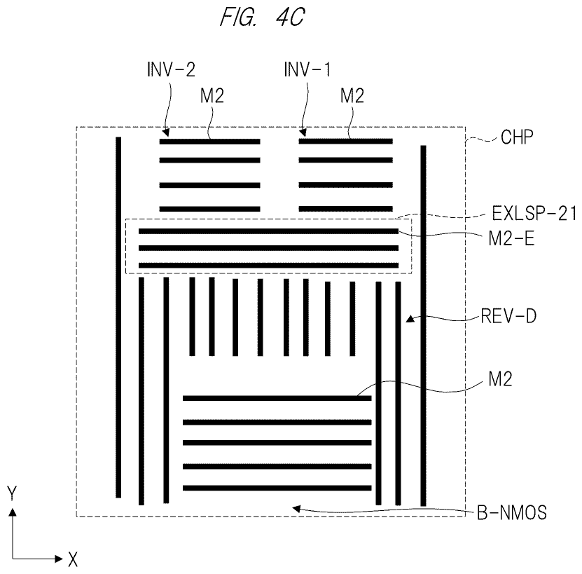

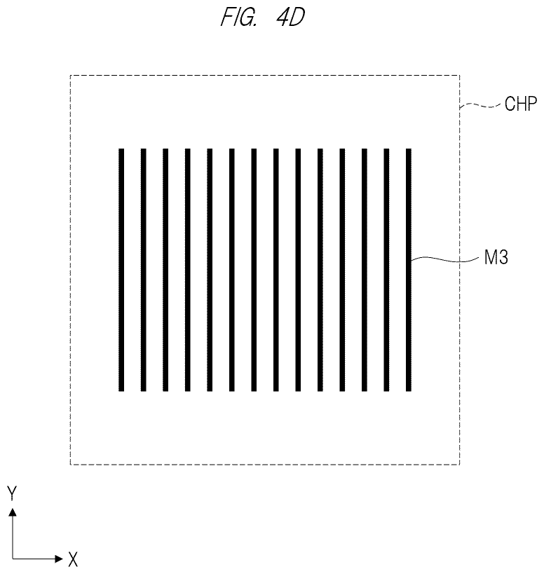

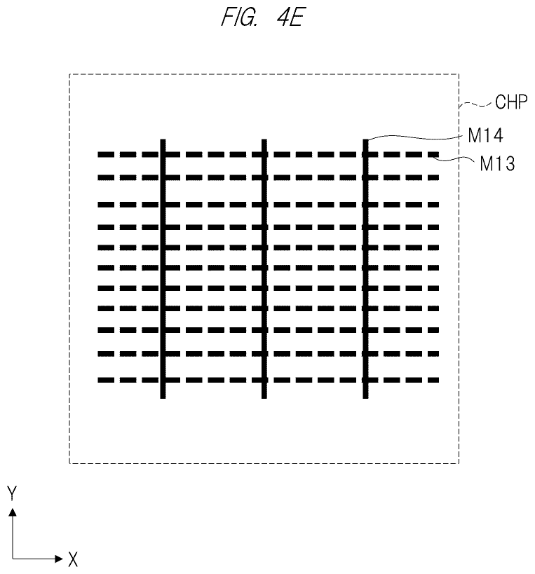

FIGS. 4A to 4E are diagrams for describing layers according to the first embodiment. FIGS. 4A to 4E schematically illustrate portions corresponding to the inverter circuits INV-1 and INV-2, the dedicated wiring region EXLSP-21, the reverse diode REV-D, and the discharge switch circuit B-NMOS in the layout of the ESD protection circuit EDSP illustrated in FIG. 3. Here, FIG. 4A illustrates a diffusion layer formed on the semiconductor chip CHP, FIG. 4B illustrates a first metal layer formed on the diffusion layer, and FIG. 4C illustrates a second metal layer formed on the diffusion layer and closest to the first metal layer. FIG. 4D illustrates an example of a third metal layer to a twelfth metal layer which are upper layers of the second metal layer, and FIG. 4E illustrates a thirteenth metal layer and a fourteenth metal layer which are upper layers of the twelfth metal layer. Although not particularly limited, the thirteenth metal layer and the fourteenth metal layer are used to supply the power supply voltage VCC and the ground voltage, and the first metal layer to the twelfth metal layer are used to connect elements and circuits, or the like. In the present specification, with respect to the diffusion layer (first layer), the first metal layer to the twelfth metal layer, which are upper layers of the diffusion layer, are hereinafter also referred to as a second layer.

In FIG. 4A, solid lines D-AR indicate diffusion regions formed on the surface of the semiconductor chip CHP, and solid lines G-AR indicate gate electrodes formed on the surface of the semiconductor chip CHP with the gate insulating film interposed therebetween. The MOS transistors constituting the inverter circuits INV-1 and INV-2 and the discharge switch circuit B-NMOS include the diffusion region D-AR and the gate electrode G-AR. In addition, the reverse diode REV-D also includes the diffusion region D-AR. Incidentally, in FIG. 4A, diffusion regions of different conductivity types are also illustrated to be identical for the sake of schematic illustration.

In FIG. 4A, a region surrounded by a broken line indicates the dedicated wiring region EXLSP-21 described in FIG. 3. In the first embodiment, the elements constituting the ESD protection circuit ESDP are not formed in the dedicated wiring region EXLSP-21. That is, in FIG. 4A, a portion of the dedicated wiring region EXLSP-21 corresponds to the surface of the semiconductor chip CHP.

In FIG. 4B, M1 indicates first-layer wirings formed using the first metal layer formed on the diffusion layer formed on the semiconductor chip CHP with the insulating layer (not illustrated) interposed therebetween. In addition, in FIG. 4B, M1-E indicates first-layer wirings formed using the first metal layer formed on the dedicated wiring region EXLSP-21 in the semiconductor chip CHP with the insulating layer (not illustrated) interposed therebetween. Since the diffusion region D-AR and the gate electrode G-AR are not formed in the dedicated wiring region EXLSP-21 as illustrated in FIG. 4A, the first-layer wirings M1-E are formed on the surface of the semiconductor chip CHP with the insulating layer (not illustrated) interposed therebetween.

In FIG. 4C, M2 indicates second-layer wirings formed using the second metal layer made of metal and formed on the first metal layer, formed on the semiconductor chip CHP, with the insulating layer (not illustrated) interposed therebetween. Further, in FIG. 4C, M2-E indicates second-layer wirings formed using the second metal layer made of metal and formed on the first metal layer with the insulating layer (not illustrated) interposed therebetween in the dedicated wiring region EXLSP-21.

As illustrated in FIG. 4B, in principle, the first-layer wirings M1 are formed to extend in the Y direction and be arranged side by side in the X direction. On the other hand, as illustrated in FIG. 4C, the second-layer wirings M2 are formed to extend in the X direction and be arranged side by side in the p Y direction in principle. As a result, elements such as the MOS transistors can be connected to form the inverter circuits INV-1 and INV-2 and the discharge switch circuit B-NMOS by using the first-layer wirings M1 and the second-layer wirings M2. For example, the inverter circuit INV-1 can be achieved by connecting the diffusion regions to be source regions and drain regions of the MOS transistors (FIG. 2, for example, N1 and P1) by the first-layer wirings M1 and the second-layer wirings M2 via openings of the insulating layer.

As illustrated in FIG. 4B, in the dedicated wiring region EXLSP-21, the first-layer wirings M1-E are formed to extend in the X direction and be arranged side by side in the Y direction. In addition, as illustrated in FIG. 4C, the second-layer wirings M2-E are also formed to extend in the X direction and be arranged side by side in the Y direction. As will be described later with reference to the drawings, openings are provided in the insulating layer between the first-layer wirings M1-E and the second-layer wirings M2-E, and the first-layer wirings M1-E and the second-layer wirings M2-E are electrically connected by via-holes.

A plurality of metal layers (in the first embodiment, the third metal layer to the twelfth metal layer) are formed above the second-layer wirings formed using the second metal layer illustrated in FIG. 4C. FIG. 4D illustrates, as an example, third-layer wirings formed using the third metal layer among these metal layers. In FIG. 4D, M3 indicates the third-layer wirings, and the third-layer wirings M3 are formed to extend in the Y direction and be arranged side by side in the X direction.

In the first embodiment, a plurality of circuits formed using the diffusion layer, the first metal layer, and the second metal layer are connected by the third-layer wirings to the twelfth-layer wirings formed using the third metal layer to the twelfth metal layer. For example, as described above, the inverter circuit INV-1 is achieved by connecting elements by the first-layer wirings M1 formed using the first metal layer and the second-layer wirings M2 formed using the second metal layer, and the electrical connection between the inverter circuit INV-1 and the discharge switch circuit B-NMOS is achieved by the third-layer wirings to the twelfth-layer wirings formed using the third metal layer to the twelfth metal layer and wirings disposed in the dedicated wiring region EXLSP-21. Here, the connection between the inverter circuit INV-1 and the discharge switch circuit B-NMOS has been described as an example, but the same applies to the connection between the inverter circuit INV-2 and the discharge switch circuit B-NMOS.

The thirteenth metal layer and the fourteenth metal layer are formed above the twelfth metal layer. FIG. 4E illustrates the thirteenth metal layer and the fourteenth metal layer formed above the twelfth metal layer on the surface of the semiconductor chip CHP. In FIG. 4E, broken lines M13 indicate thirteenth-layer wirings formed using the thirteenth metal layer, and solid lines M14 indicate fourteenth-layer wirings formed using the fourteenth metal layer. Although not particularly limited, the thirteenth-layer wirings M13 are formed to extend in the X direction and be arranged side by side in the Y direction, and the fourteenth-layer wirings M14 are disposed to extend in the Y direction and be arranged side by side in the X direction.

In the first embodiment, some thirteenth-layer wirings M13 among the plurality of thirteenth-layer wirings M13 formed using the thirteenth metal layer and some fourteenth-layer wirings M14 among the plurality of fourteenth-layer wirings M14 formed using the fourteenth metal layer are electrically connected to form the power supply wiring LVCC. In addition, the other thirteenth-layer wirings M13 among the plurality of thirteenth-layer wirings M13 and the other fourteenth-layer wirings M14 among the plurality of fourteenth-layer wirings M14 are electrically connected to form the ground wiring LVSS.

The connection between a circuit (for example, the inverter circuit INV-1) constituting the ESD protection circuit ESDP and the power supply wiring LVCC is achieved by connecting the inverter circuit INV-1 and the thirteenth-layer wirings M13 and the fourteenth-layer wirings M14 constituting the power supply wiring LVCC using the third-layer wirings M3 to the twelfth-layer wirings M12. Similarly, the connection between the inverter circuit INV-1 and the ground wiring LVSS is also achieved by connecting the inverter circuit INV-1 and the thirteenth-layer wirings M13 and the fourteenth-layer wirings M14 constituting the ground wiring LVSS using the third-layer wiring M3 to the twelfth-layer wiring M12.

### Wiring Layout in Dedicated Wiring Region

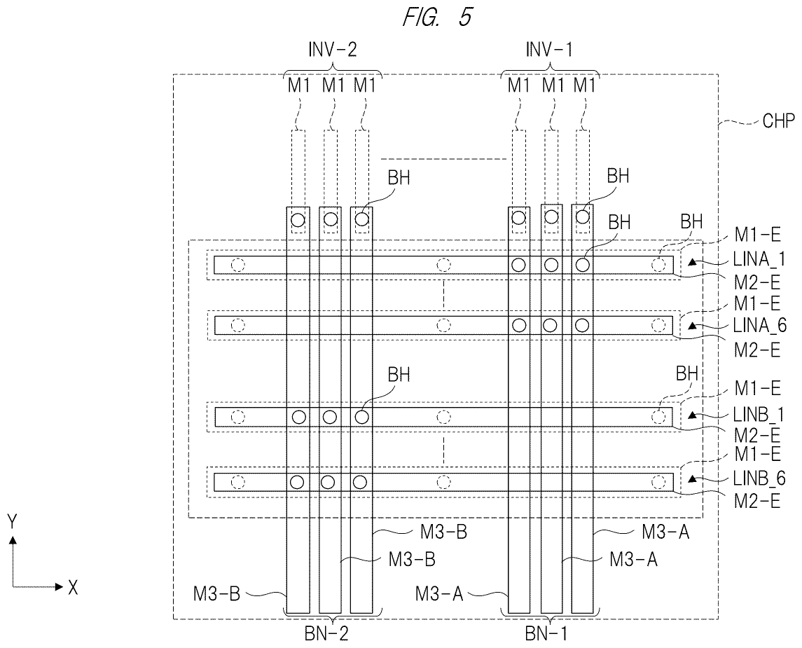

Next, a detailed layout of the dedicated wiring region EXLSP-21 will be described with reference to the drawings. FIG. 5 is a plan view illustrating a wiring layout in the dedicated wiring region according to the first embodiment. As illustrated in FIG. 3, the internal wirings LINA and LINB are disposed in the dedicated wiring region EXLSP-21, and the inverter circuits INV-1 and INV-2 and the gate electrodes of the NMOS transistors BN1 and BN2 of the discharge switch circuit B-NMOS are connected using the internal wirings LINA and LINB. In FIG. 5, the first-layer wirings M1 and M1-E formed using the first metal layer are illustrated in broken lines, and the second-layer wirings M2 and M2-E formed using the second metal layer and the third-layer wirings M3 formed using the third metal layer are illustrated in solid lines. In FIG. 5, BH indicates via-holes.

Although not particularly limited, in the first embodiment, the internal wiring LINA is constituted by six wirings LINA_1 to LINA_6, and the internal wiring LINB is also constituted by six wirings LINB_1 to LINB_6.

Each of the wirings LINA_1 to LINA_6 and LINB_1 to LINB_6 is constituted by the first-layer wiring M1-E formed of the first metal layer and the second-layer wiring M2-E formed of the second metal layer. That is, as illustrated in FIG. 5, when viewed in a plan view, the first-layer wiring M1-E and the second-layer wiring M2-E are formed so as to overlap each other, and the first-layer wiring M1-E and the second-layer wiring M2-E are electrically connected by the via-hole BH illustrated in a broken line. Although the first-layer wiring M1-E is drawn larger than the second-layer wiring M2-E such that the wirings can be easily distinguished in FIG. 5, the invention is not limited thereto.

In FIG. 5, the first-layer wirings M1 disposed along the Y direction outside the dedicated wiring region EXLSP-21 indicate the first-layer wirings of the inverter circuits INV-1 and INV-2. In FIG. 5, the three first-layer wirings M1 parenthesized by reference sign INV-1 are connected to the drain region of the PMOS transistor P1 and the drain region of the NMOS transistor N1 as described with reference to FIG. 2. Similarly, the three first-layer wirings M1 parenthesized by the reference sign INV-2 are connected to a drain region of the PMOS transistor P2 and a drain region of the NMOS transistor N2 as described with reference to FIG. 2.

Although not particularly limited, the first-layer wirings M1 of the inverter circuit INV-1 are connected to third-layer wirings M3-A formed of the third metal layer by the via-holes BH illustrated in circles, and the third-layer wirings M3-A are connected to the first-layer wiring M1-E and the second-layer wiring M2_E constituting each of the internal wirings LINA_1 to LINA_6 by the via-holes BH. In addition, the third-layer wirings M3-A are connected to the gate electrode of the NMOS transistor BN1 constituting the discharge switch circuit B-NMOS.

Similarly, the first-layer wirings M1 of the inverter circuit INV-2 are connected to third-layer wirings M3-B formed of the third metal layer by the via-holes BH, and the third-layer wirings M3-B are connected to the first-layer wiring M1-E and the second-layer wiring M2_E constituting each of the internal wirings LINB_1 to LINB_6 by the via-holes BH. The third-layer wirings M3-B are connected to the gate electrode of the NMOS transistor BN2 constituting the discharge switch circuit B-NMOS.

Wirings (hereinafter, also referred to as a first wiring and a third wiring) connecting the inverter circuits INV-1 and INV-2 and the discharge switch circuit B-NMOS, that is, the first wiring and the third wiring connecting the trigger circuit TGC and the discharge switch circuit B-NMOS illustrated in FIG. 1 include the internal wirings (a first portion) LINA and LINB extending in the X direction and the third-layer wirings (a second portion) M3-A and M3-B extending in the Y direction intersecting the X direction. In this case, the plurality of (three in FIG. 5) third-layer wirings M3-A (M3-B) are electrically connected to be bundled by the plurality of internal wirings LINA_1 to LINA_6 (LINB_1 to LINB_6). Therefore, a combined resistance value of the third-layer wirings M3-A (M3-B) is equal to or lower than a resistance value of the internal wiring LINA (LINB). In addition, the first-layer wiring M1-E and the second-layer wiring M2-E are electrically connected in parallel also in the internal wiring LINA (LINB) used for bundling the third-layer wirings M3-A (M3-B), a combined resistance value of the internal wiring LINA (LINB) can be reduced, and the third-layer wirings M3-A (M3-B) can be bundled by a wiring having a low resistance value.

FIG. 5 illustrates an example in which the third-layer wiring formed using the third metal layer is used as the wiring connecting the inverter circuits INV-1 and INV-2, the internal wiring (LINA, LINB), and the discharge switch circuit B-NMOS, but the invention is not limited thereto, and any of the fourth-layer wiring to the twelfth-layer wiring may be used. In addition, the number of wirings constituting each of the internal wirings LINA and LINB is not limited to six, and may be, for example, one. Furthermore, for example, the inverter circuit and the internal wiring and the internal wiring and the discharge switch circuit may be connected by mutually different third-layer wirings M3-A (M3-B).

FIG. 5 illustrates an example in which the internal wirings LINA and LINB are laid in parallel in the X direction, but the invention is not limited thereto, and for example, a part of the internal wirings LINA and LINB may be laid in parallel.

### Region Including Dedicated Wiring Region EXLSP-11

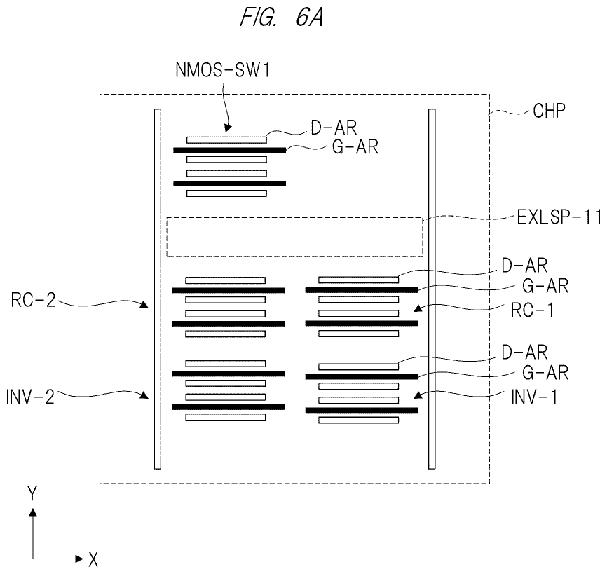

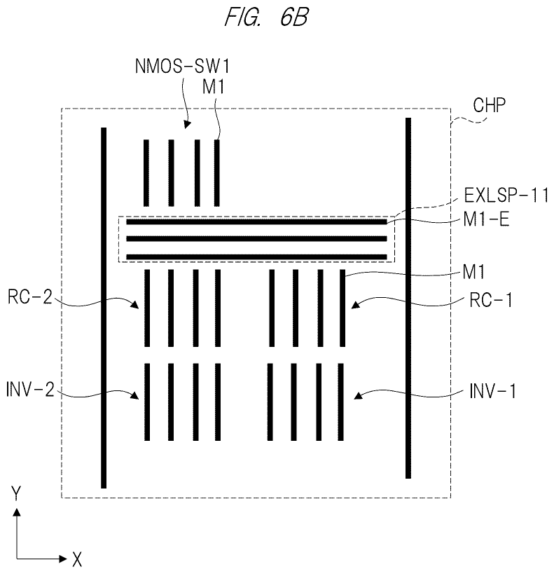

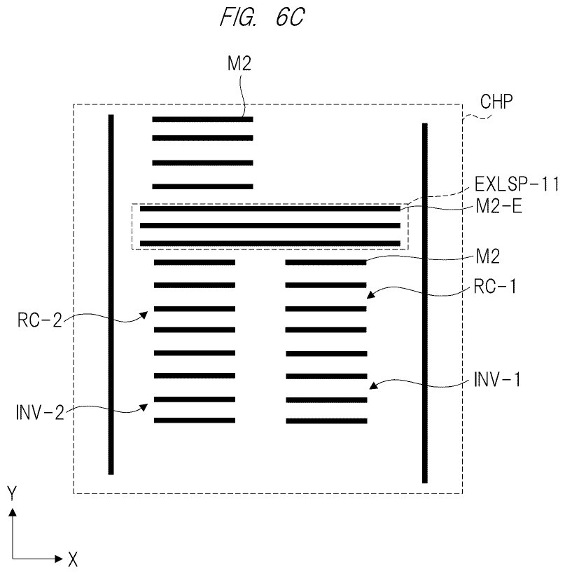

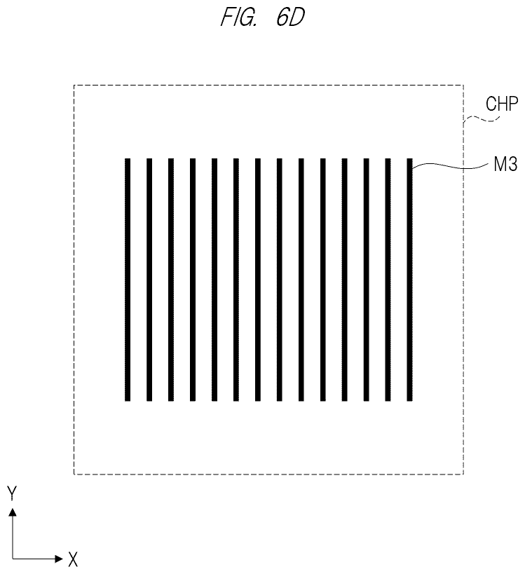

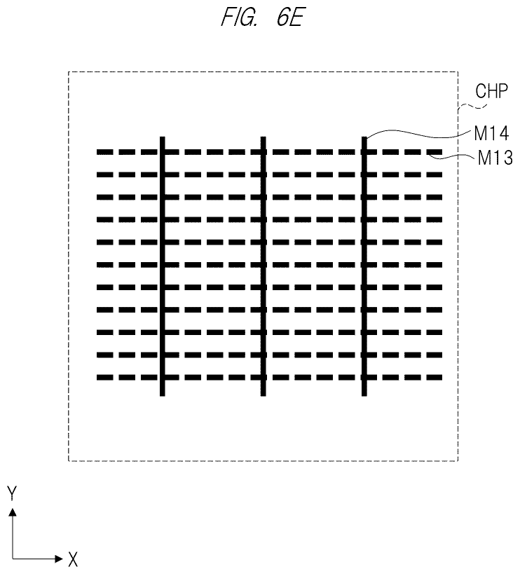

FIGS. 6A to 6E are diagrams for describing layers according to the first embodiment. FIGS. 6A to 6E schematically illustrate portions corresponding to the NMOS switch circuit NMOS-SW1, the dedicated wiring region EXLSP-11, the time constant circuits RC-1 and RC-2, and the inverter circuits INV-1 and INV-2 in the layout of the ESD protection circuit EDSP illustrated in FIG. 3. Here, FIGS. 6A to 6E are similar to FIGS. 4A to 4E. That is, FIG. 6A illustrates a diffusion layer formed on the semiconductor chip CHP, FIG. 6B illustrates a first metal layer formed on the diffusion layer, and FIG. 6C illustrates a second metal layer formed on the diffusion layer with an insulating layer interposed therebetween. In addition, FIG. 6D illustrates a third metal layer among the third metal layer to a twelfth metal layer formed on the second metal layer with an insulating layer interposed therebetween, and FIG. 6E illustrates a thirteenth metal layer and a fourteenth metal layer formed on the twelfth metal layer with an insulating layer interposed therebetween.

Since FIGS. 6A to 6E are similar to FIGS. 4A to 4E, detailed description thereof is omitted except for the dedicated wiring region EXLSP-11. In the dedicated wiring region EXLSP-11, as illustrated in FIG. 6B, the first-layer wirings M1-E formed of the first metal layer are formed on the surface of the semiconductor chip CHP with the insulating layer interposed therebetween. Thereafter, as illustrated in FIG. 6C, the second-layer wirings M2-E formed of the second metal layer are formed on the first-layer wirings M1-E with the insulating layer interposed therebetween in the dedicated wiring region EXLSP-11. When viewed in a plan view, the first-layer wiring M1-E and the second-layer wiring M2-E disposed so as to overlap each other are connected by a via-hole and used as the internal wiring LINC. The internal wiring LINC is connected to the NMOS switch circuit NMOS-SW1, the time constant circuits RC-1 and RC-2, and the inverter circuits INV-1 and INV-2 by the third-layer wiring M3 and the like illustrated in FIG. 6D.

### Wiring Layout in Dedicated Wiring Region

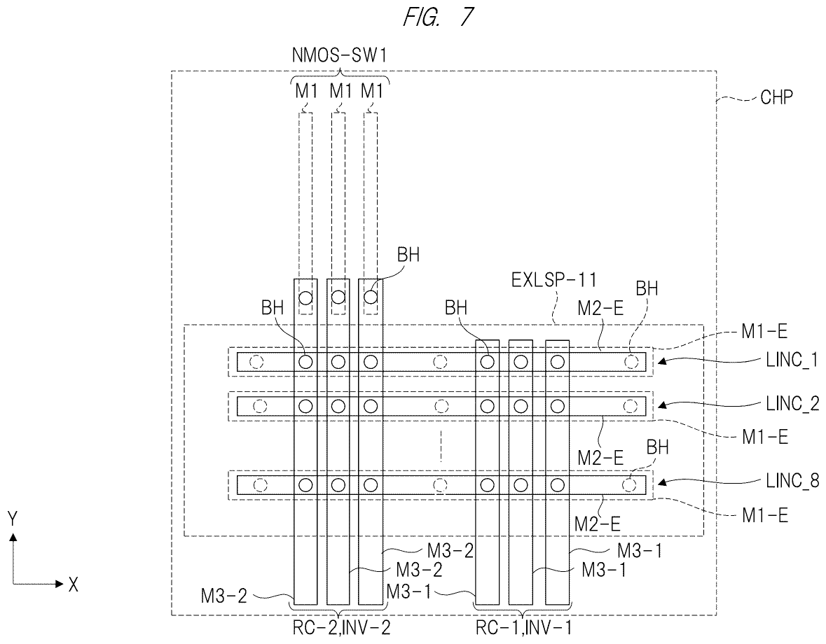

Next, a detailed layout of the dedicated wiring region EXLSP-11 will be described with reference to the drawings. FIG. 7 is a plan view illustrating a wiring layout in the dedicated wiring region according to the first embodiment. As illustrated in FIG. 3, the internal wiring LINC is disposed in the dedicated wiring region EXLSP-11, and the NMOS switch circuit NMOS-SW1, the inverter circuits INV-1 and INV-2, and the time constant circuits RC-1 and RC-2 are connected using the internal wiring LINC. Also in FIG. 7, the first-layer wirings M1 and M1-E formed using the first metal layer are illustrated in broken lines, and the second-layer wirings M2 and M2-E formed using the second metal layer and the third-layer wirings M3 formed using the third metal layer are illustrated in solid lines.

Although not particularly limited, the internal wiring LINC is constituted by eight wirings LINC_1 to LINC_8 in the first embodiment.

Similarly to the internal wirings LINA_1 to LINA_6 described above, each of the wirings LINC_1 to LINC_8 is constituted by the first-layer wiring M1-E formed of the first metal layer and the second-layer wiring M2-E formed of the second metal layer. That is, as illustrated in FIG. 7, when viewed in a plan view, the first-layer wiring M1-E and the second-layer wiring M2-E are formed so as to overlap each other, and the first-layer wiring M1-E and the second-layer wiring M2-E are electrically connected by the via-hole BH. Also in FIG. 7, the first-layer wiring M1-E is drawn larger than the second-layer wiring M2-E such that the wirings can be easily distinguished.

In FIG. 7, the first-layer wirings M1 disposed along the Y direction outside the dedicated wiring region EXLSP-11 indicate the first-layer wirings of the NMOS switch circuit NMOS-SW1. In FIG. 7, the three first-layer wirings M1 parenthesized by the reference sign NMOS-SW1 are connected to, for example, a source region of the NMOS transistor N3 as described with reference to FIG. 2.

Although not particularly limited, the first-layer wirings M1 of the NMOS switch circuit NMOS-SW1 are connected to third-layer wirings M3-2 formed of the third metal layer by the via-holes BH illustrated in circles, and the third-layer wirings M3-2 are connected to the first-layer wiring M1-E and the second-layer wiring M2_E constituting each of the internal wirings LINC_1 to LINC_8 by the via-holes BH. In addition, these third-layer wirings M3-2 are connected to the time constant circuit RC-2 and the inverter circuit INV-2.

Similarly, the third-layer wiring M3-1 are connected to the first-layer wiring M1-E and the second-layer wiring M2_E constituting each of the internal wirings LINC_1 to LINC_8 by the via-holes BH. These third-layer wirings M3-1 are connected to the time constant circuit RC-2 and the inverter circuit INV-2.

A wiring (hereinafter, also referred to as a second wiring) connecting the NMOS switch circuit NMOS-SW1, the time constant circuits RC-1 and RC-2, and the inverter circuits INV-1 and INV-2 includes the internal wiring (a first portion) LINC extending in the X direction and the third-layer wirings (a second portion) M3-1 and M3-2 extending in the Y direction intersecting the X direction. In this case, since the respective third-layer wirings M3-1 and M3-2 are electrically connected so as to be bundled by the plurality of internal wirings LINC_1 to LINC_8, a resistance value of the third-layer wirings M3-1 and M3-1 is equal to or lower than a resistance value of the internal wiring LINC.

FIG. 7 illustrates an example in which the third-layer wiring formed of the third metal layer is used as the wiring connecting the NMOS switch circuit NMOS-SW1, the internal wiring (LINC), the time constant circuits RC-1 and RC-2, and the inverter circuits INV-1 and INV-2, but the invention is not limited thereto, and any of the fourth-layer wiring to the twelfth-layer wiring may be used. In addition, the number of wirings constituting the internal wiring LINC is eight as an example, but is not limited thereto, and may be one, for example.

### Layout of Power Supply Wiring and Ground Wiring

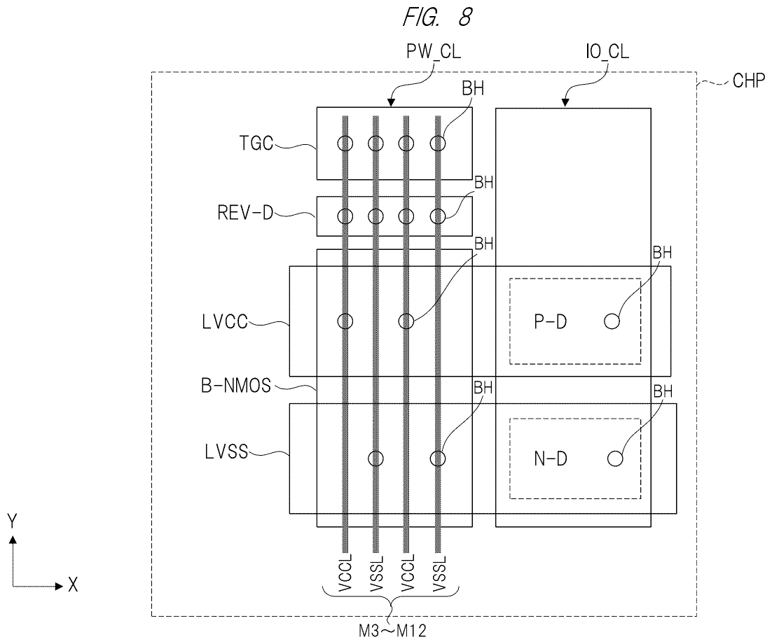

FIG. 8 is a plan view illustrating a layout of the power supply wiring and the ground wiring according to the first embodiment. FIG. 8 illustrates a layout of portions related to the signal cell IO_CL and the power supply cell PW_CL illustrated in FIG. 1.

In FIG. 8, reference signs P-D and N-D denote the protection diodes provided in the signal cell IO_CL. Broken lines drawn so as to surround the symbols P-D and N-D indicate diffusion regions constituting the protection diodes P-D and N-D.

In FIG. 8, the power supply wiring LVCC is configured by electrically connecting some thirteenth-layer wirings M13 among the plurality of thirteenth-layer wirings M13 and some fourteenth-layer wirings M14 among the plurality of fourteenth-layer wirings M14 as described above. In addition, the other thirteenth-layer wirings M13 among the plurality of thirteenth-layer wirings M13 and the other fourteenth-layer wirings M14 among the plurality of fourteenth-layer wirings M14 are electrically connected to form the ground wiring LVSS.

As illustrated in FIG. 8, the power supply wiring LVCC extends so as to overlap the discharge switch circuit B-NMOS and the protection diode P-D, and is electrically connected to a drain region of the NMOS transistor BN1 (FIG. 2) and the protection diode P-D when viewed in a plan view. In addition, the ground wiring LVSS extends so as to overlap the discharge switch circuit B-NMOS and the protection diode N-D, and is electrically connected to a source region of the NMOS transistor BN2 (FIG. 2) and the protection diode N-D.

The power supply wiring LVCC is connected to wirings VCCL, which are constituted by the third-layer wiring M3 to the twelfth-layer wiring M12 and extend in the Y direction, by the via-holes BH, and the ground wiring LVSS is connected to wirings VSSL which are constituted by the third-layer wiring M3 to the twelfth-layer wiring M12 and extend in the Y direction by the via-holes BH. The wirings VCCL and VSSL are connected to the inside of the trigger circuit TGC and the reverse diode REV-D by the via-holes BH to supply the power supply voltage VCC and the ground voltage VSS.

That is, the power supply wiring LVCC and the ground wiring LVSS corresponding to the main discharge wiring are connected to the discharge switch circuit B-NMOS and the protection diodes P-D and N-D. On the other hand, for example, the inside of the trigger circuit TGC is connected to the main discharge wiring via the wirings VCCL and VSSL.

It is considered that discharge performance is deteriorated if the NMOS transistors BN1 and BN2 are disposed in a distributed manner, and thus, the NMOS transistors BN1 and BN2 constituting the discharge switch circuit B-NMOS are disposed adjacent to each other.

Since the reverse diode REV-D forms a discharge path when a high voltage is applied to the ground terminal, the reverse diode REV-D is also desirably disposed close to the power supply wiring LVCC and the ground wiring LVSS. However, in the first embodiment, the reverse diode REV-D is disposed between the discharge switch circuit B-NMOS and the trigger circuit TGC in order to give priority on disposing the NMOS transistors BN1 and BN2 adjacent to each other and to prevent a dead space from occurring in the adjacent signal cell IO_CL. Although not illustrated in FIG. 8, the internal wirings LINA to LINC extend in the X direction in the trigger circuit TGC. Therefore, the reverse diode REV-D is disposed along the X direction between the internal wirings LINA to LINC in the trigger circuit TGC and the NMOS transistors BN1 and BN2.

### Layout of Discharge Switch Circuit

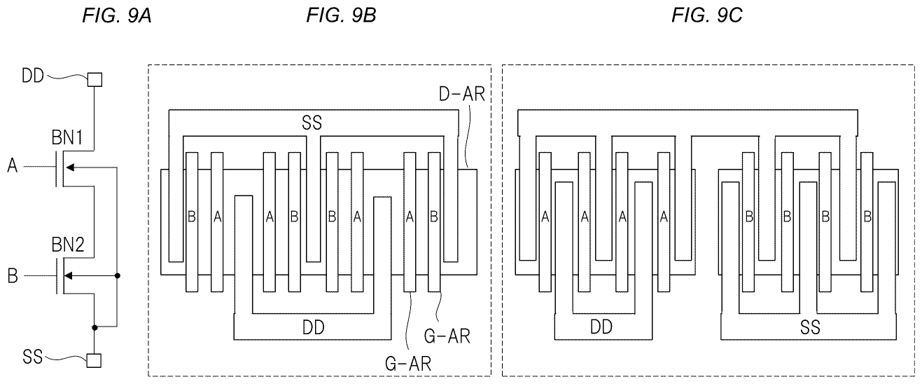

FIGS. 9A to 9C are diagrams for describing the discharge switch circuit according to the first embodiment. Here, FIG. 9A illustrates a circuit configuration of the discharge switch circuit B-NMOS, and FIGS. 9B and 9C are diagrams illustrating layouts of the discharge switch circuit.

The configuration of the discharge switch circuit B-NMOS illustrated in FIG. 9A is similar to that illustrated in FIG. 1. A difference in FIG. 9A is that the gate electrode of the NMOS transistor BN1 is denoted by reference sign A, the gate electrode of the NMOS transistor BN2 is denoted by reference sign B, an electrode of the drain region of the NMOS transistor BN1 is denoted by reference sign DD, and an electrode of the source region of the NMOS transistor BN2 is denoted by SS.

In the layout illustrated in FIG. 9B, the gate electrode A of the NMOS transistor BN1 and the gate electrode B of the NMOS transistor BN2 are disposed in series between the drain electrode DD and the source electrode SS. On the other hand, in the layout illustrated in FIG. 9C, the gate electrodes A and B of the NMOS transistors BN1 and BN2 are separately disposed between the drain electrodes DD and between the source electrodes SS, respectively.

When the layout illustrated in FIG. 9B is adopted, it is possible to reduce an occupied area of the discharge switch circuit B-NMOS and improve heat dissipation. Therefore, the layout illustrated in FIG. 9B is adopted in the discharge switch circuit B-NMOS according to the first embodiment.

In the first embodiment, the source regions, the drain regions, and the like of the MOS transistors and the gate electrodes are formed in the first layer (diffusion layer) as described with reference to FIGS. 4A to 4E and FIGS. 6A to 6E. Therefore, it can be considered that the MOS transistor and the trigger circuit TGC including the MOS transistor and the like are formed in the first layer. In this regard, it can be considered that the internal wirings and the wirings (for example, the third-layer wiring) electrically connected to the internal wirings are formed in the second layer which is an upper layer of the first layer. Furthermore, it can be considered that the power supply wiring LVCC and the ground wiring LVSS are formed in an upper layer of the second layer.

In the ESD protection circuit ESDP according to the first embodiment, the internal wirings constituted by wirings in the same layer as the first-layer wiring and the second-layer wiring used in the circuits constituting the ESD protection circuit are disposed in the dedicated wiring regions, and the wirings (for example, the third-layer wirings) connecting the circuits are bundled by the internal wirings. This makes it possible to reduce the wiring resistance connecting the circuits constituting the ESD protection circuit ESDP, and to suppress the deterioration of the ESD protection function.

### Second Embodiment

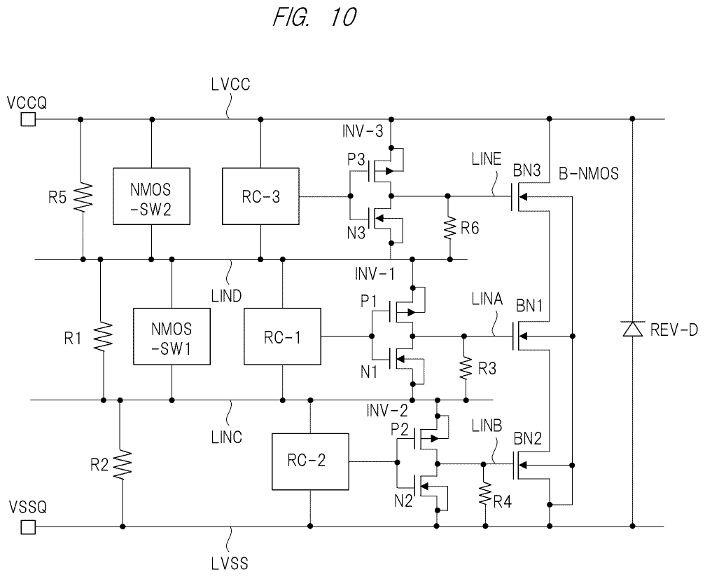

FIG. 10 is a block diagram illustrating a configuration of an ESD protection circuit according to the second embodiment. In the ESD protection circuit according to the second embodiment, the discharge switch circuit B-NMOS connected to a main discharge wiring includes three-stage MOS transistors whose source-drain paths are connected in series. As a result, a MOS transistor having a lower withstand voltage can be adopted as the discharge switch circuit B-NMOS.

FIG. 10 is similar to FIG. 2. The ESD protection circuit ESDP illustrated in FIG. 10 is different from the ESD protection circuit of FIG. 2 in terms of further including resistors R5 and R6, an NMOS switch circuit NMOS-SW2, a time constant circuit RC-3, an inverter circuit INV-3, and an NMOS transistor BN3. In addition, the ESD protection circuit ESDP of FIG. 10 is also different in terms of further including internal wirings LIND and LINE.

As illustrated in FIG. 10, the resistor R1, the NMOS switch circuit NMOS-SW1, the time constant circuit RC-1, and the inverter circuit INV-1 are connected to the internal wiring LIND instead of the power supply wiring LVCC. The resistor R5, the NMOS switch circuit NMOS-SW2, the time constant circuit RC-3, and the inverter circuit INV-3 are connected in parallel between the power supply wiring LVCC and the internal wiring LIND. In addition, an output node (node to which a drain region of the PMOS transistor P3 and a drain region of the NMOS transistor N5 are connected) of the inverter circuit INV-3 is connected to a gate electrode of the NMOS transistor BN3 via the internal wiring LINE. In addition, the resistor R6 is connected between the internal wiring LIND and the internal wiring LINE. As illustrated in FIG. 10, the NMOS transistors BN1 to BN3 are connected between the power supply wiring LVCC and the ground wiring LVSS such that source-drain paths are connected in series between the power supply wiring and the ground wiring.

The NMOS switch circuit NMOS-SW2, the time constant circuit RC-3, the inverter circuit INV-3, and the resistors R5 and R6 function similarly to the NMOS switch circuit NMOS-SW1, the time constant circuit RC-1, the inverter circuit INV-1, and the resistors R1 and R3 described in FIG. 2, and thus, detailed description thereof will be omitted. When a steep high voltage is applied to the power supply terminal VCCQ, each of the internal wirings LINA to LINE changes toward a voltage of the power supply wiring LVCC, and the NMOS transistors BN1 to BN3 are turned on. This makes current flow between the power supply wiring LVCC and the ground wiring LVSS via the discharge switch circuit B-NMOS, and a protected circuit can be prevented from being destroyed.

### Layout of ESD Protection Circuit

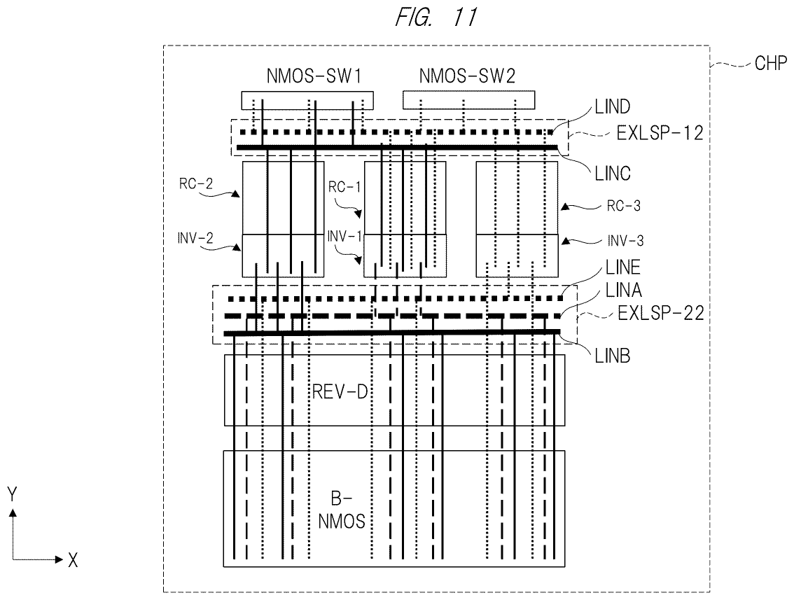

FIG. 11 is a plan view illustrating a layout of the ESD protection circuit according to the second embodiment. That is, FIG. 11 illustrates an example of the layout of the ESD protection circuit illustrated in FIG. 10. This FIG. 11 is similar to FIG. 3. A difference in FIG. 11 is that the NMOS switch circuit NMOS-SW2 is disposed next to the NMOS switch circuit NMOS-SW1 (X direction), and the time constant circuit RC-3 and the inverter circuit INV-3 are disposed between the NMOS switch circuit NMOS-SW2 and the reverse diode REV-D (Y direction).

In addition, the dedicated wiring regions EXLSP-11 and EXLSP-21 illustrated in FIG. 3 are increased in area to be disposed as dedicated wiring regions EXLSP-12 and EXLSP-22. The internal wirings LINC and LIND are disposed in the dedicated wiring region EXLSP-12, and the internal wirings LINA, LINB, and LINE are disposed in the dedicated wiring region EXLSP-22. Each of these internal wirings LINA to LINE is constituted by the first-layer wiring M1-E and the second-layer wiring M2-E as described in the first embodiment. In addition, the internal wirings and circuit blocks (for example, the NMOS switch circuits, the inverter circuits, the time constant circuits, and the like) in the ESD protection circuit are connected by the third-layer wiring M3 to the twelfth-layer wiring M12.

Also in the second embodiment, the internal wirings constituted by wirings in the same layer as the first-layer wiring and the second-layer wiring used in the circuits constituting the ESD protection circuit are disposed in the dedicated wiring regions, and the wirings (for example, the third-layer wirings) connecting the circuits are bundled by the internal wirings. This makes it possible to reduce the wiring resistance connecting the circuits constituting the ESD protection circuit ESDP, and to suppress the deterioration of the ESD protection function.

In addition, the MOS transistor having the lower withstand voltage can be used the NMOS transistor (BN1 to BN3) constituting the discharge switch circuit B-NMOS in the second The withstand voltage of the NMOS transistor is embodiment. determined by, for example, a film thickness of a gate insulating film. When a newer-generation process is adopted, the film thickness of the gate insulating film becomes thinner, and the withstand voltage of the NMOS transistor (BN1 to BN3) decreases.

When the number of stages of the NMOS transistors constituting the discharge switch circuit is increased as in the second embodiment, it is possible to prevent a decrease in a voltage at which the protection function operates.

The MOS transistor may be a Fin-type MOS transistor limited to a planar type MOS transistor.

The invention made by the present inventors has been described in detail based on the embodiments as above, but the present invention is not limited to the embodiments described above, and, needless to say, various types of modifications can be made in the range of not departing from a gist thereof.

What is claimed is:

1. A semiconductor device comprising:
a semiconductor chip having a plurality of layers formed on a surface,
wherein in the plurality of layers,
a first power supply wiring to which a power supply voltage is supplied,
a second power supply wiring to which a ground voltage is supplied,
a MOS transistor connected to the first power supply wiring and the second power supply wiring and configured to electrically short-circuit the first power supply wiring and the second power supply wiring, and
a trigger circuit electrically connected to a first gate electrode of the MOS transistor via a first wiring and configured to output a first control signal for controlling the first gate electrode, are formed,
wherein the MOS transistor and the trigger circuit are formed in a first layer of the plurality of layers,
wherein the first wiring is formed in a second layer which is an upper layer of the first layer, and
wherein the first wiring includes:
a first portion extending in a first direction; and
a second portion which extends in a second direction intersecting the first direction and is electrically connected to the first portion.

2. The semiconductor device according to claim 1,
wherein a resistance value of the second portion of the first wiring is equal to or lower than a resistance value of the first portion of the first wiring.

3. The semiconductor device according to claim 2,
wherein the first wiring includes a plurality of wirings.

4. The semiconductor device according to claim 3,
wherein in a plan view from the surface of the semiconductor chip, the second portion of the first wiring is disposed between the trigger circuit and the MOS transistor, and the second portion of the first wiring, the trigger circuit, and the MOS transistor are disposed to face the first direction.

5. The semiconductor device according to claim 4,
wherein the trigger circuit includes:
a switch circuit electrically connected to the first power supply wiring;
a first RC circuit electrically connected to the first power supply wiring; and
a first inverter circuit electrically connected to the switch circuit and the first RC circuit via a second wiring, and electrically connected to the first gate electrode of the MOS transistor via the first wiring, and
wherein the second wiring is formed in the second layer, and includes a first portion extending in the first direction and a second portion extending in the second direction.

6. The semiconductor device according to claim 5,
wherein a resistance value of the second portion of the second wiring is equal to or lower than a resistance value of the first portion of the second wiring.

7. The semiconductor device according to claim 6,
wherein the second wiring includes a plurality of wirings.

8. The semiconductor device according to claim 7,
wherein in the plan view, the first RC circuit is disposed between the switch circuit and the first inverter circuit, and the first RC circuit, the switch circuit, and the first inverter circuit are disposed to face the first direction, and
wherein the second portion of the second wiring is disposed between the switch circuit and the first RC circuit.

9. The semiconductor device according to claim 8,
wherein the trigger circuit further includes:
a second RC circuit electrically connected to the switch circuit via the second wiring; and
a second inverter circuit electrically connected to the switch circuit and the second RC circuit via the second wiring, electrically connected to a second gate electrode of the MOS transistor in a subsequent stage of the first gate electrode via a third wiring, and configured to output a second control signal to the second gate electrode of the MOS transistor, and
wherein the third wiring is formed in the second layer, and includes a first portion extending in the first direction and a second portion extending in the second direction.

10. The semiconductor device according to claim 9,
wherein a resistance value of the second portion of the third wiring is equal to or lower than a resistance value of the first portion of the third wiring.

11. The semiconductor device according to claim 10,
wherein the third wiring includes a plurality of wirings.

12. The semiconductor device according to claim 11,
wherein in the plan view, the second portion of the third wiring is disposed between the trigger circuit and the MOS transistor, and the second portion of the third wiring, the trigger circuit, and the MOS transistor are disposed so as to face the first direction, and
wherein the second portion of the third wiring is laid partially parallel with the second portion of the first wiring.

13. The semiconductor device according to claim 4, further comprising a diode connected to the first power supply wiring and the second power supply wiring and configured to electrically short-circuit the first power supply wiring and the second power supply wiring,
wherein the diode is disposed along the first direction between the second portion of the first wiring and the MOS transistor in the plan view.
